(19) United States
(12) Patent Application Publication
(10) Pub. No.: US 2019/0368026 A1
(43) Pub. Date: Dec. 5, 2019

(54) NEW HIGH TEMPERATURE AIR STABLE CERAMIC METALLIC MATERIAL USED IN SOLAR SELECTIVE SURFACE AND ITS PRODUCTION METHOD

(71) Applicant: Chufan Kang, Weihai City (CN)

(72) Inventor: Chufan Kang, Weihai City (CN)

(21) Appl. No.: 16/423,710

(22) Filed: May 28, 2019

(30) Foreign Application Priority Data
May 29, 2018 (CN) 201810532257.X

(51) Int. Cl. C23C 14/06; C22C 29/18

(52) U.S. Cl. CPC C23C 14/0688; C22C 29/18

(57) ABSTRACT

There is provided herein a high temperature air stable ceramic metallic material used in solar selective surface and its production method.

### TECHNOLOGY DOMAIN

This invention belongs to Solar technology and material technology, specifically related to a high temperature air stable ceramic metallic material used in solar selective surface and its production method.

### BACKGROUND TECHNOLOGY

Solar selective surfaces are well known. They basically consist of an infra red reflector, an absorbing layer that is transparent in the infra red region.

To increase efficiency an anti reflection layer can reduce the effects of optical mismatch between the absorbing layer and the ambient.

One way of obtaining a solar absorbing material with high infrared transmission is using a cermet, this is a dielectric ceramic doped with a metal. The metal volume fractions of such layer range from 10% to 50%. It is beneficial to use two cermets on top of each other with different metal volume fractions in a solar absorber. Best results are obtained with a first cermet containing 40% metal volume fraction and a second layer containing 20% metal volume fraction.

Luz produced high temperature solar selective surfaces with absorbing layers containing Al2O3-Mo.

However such layers do not show oxidation resistance when exposed at temperatures above 300 degree c. The Molybdenum will slowly oxidize and vaporize. Platinum has been used in high temperature air stable coatings. However it is clear that the use of Platinum increases the cost of such selective surface dramatically. Another method of increasing the air stability is by depositing an excess of aluminum inside the alumina host while co depositing a refractory metal such as W, Ni, Nb, Mo and Ta. However deposited structures are porous in nature and thus oxygen will enter the structure and oxidize the refractory metal.

### DESCRIPTION OF THE INVENTION

It is the purpose of the invention to deposit a metallic fraction, that will passivate at high temperature in air, into the dielectric. In this way the oxidation of the metal fraction will be blocked by an oxide layer grown out of the metal.

Alloys that form high temperature passivating layers are NiCr alloys, NiCrAlY, Metal silicides and Metal Titanium alloys or mixtures of the previous alloys.

Basically these layers contain a refractory metal and a metal that forms a protective oxide layer grown out of the base material. It is important that such oxide scales have a good adhesion to the base alloy and form a oxygen diffusion barrier preventing oxidation of the underlying layer.

The layer is deposited from two cathodes by reactive PVD in an oxygen argon atmosphere. It is beneficial to use opposing cathodes with the substrate positioned between the cathodes while it rotates around a central axis. One of the cathodes contain predominant aluminum or an alloy. The dielectric is formed by adding oxygen as a reactive gas in to deposition chamber and using for example a pulsed DC power supply. Another method but much slower would be to deposit the alumina or alumina alloy directly from an Alumina or Alumina alloy target by a Radio Frequency deposition.

In the case the a reactive process is used to deposit the dielectric is advantages to install the active gas inlets near the target that will supply the dielectric material. By reducing the reactive gas, an excess of for example aluminum can be generated in the dielectric. This excess aluminum would also further passivate the refractory metal particles. The other cathode contains a refractory metal and an element that forms stable oxides on the refractory metal. Such element can be Cr, Al, Ti, Si. The refractory metal can be Nb, Ta, Ni, Mo or Tungsten.

For example the cathode providing the metallic particles could be NiCr or NiCrAlY.

Power density for the high metal volume fraction are between 1.5-3.5 W/cm\hat{ }2 for both the aluminum and metallic particle providing cathode. The deposition pressure is between 0.2 to 0.8 Pa

Power density for the low metal volume fraction are between 1.5-3.5 W/cm\hat{ }2 for the aluminum providing cathode, and 0.5-1.5 W/cm2 for metallic alloy particle providing cathode. The deposition pressure is between 0.2 to 0.8 Pa

1. A cermet material used in solar selective surfaces comprising metal alloy particles that form a passivating oxide layer around the metal particle when exposed at high temperature in an oxygen containing environment, inside a ceramic dielectric.

2. The cermet material of claim 1 that requires a heat treatment above 300° in an oxidizing atmosphere to passivate.

3. The cermet material of claim 1, deposited on an infrared reflector.

4. The cermet material of claim 3, where between the cermet and the infra red reflector a diffusion barrier is deposited containing SiO2.

5. The cermet material of claim 1, where on top of the cermet an anti reflective coating is posited.

6. A cermet material deposited by reactive PVD using at least two cathodes wherein one cathode contains mostly aluminum and the other cathode contains a refractory metal mixed with an element forming an oxide layer that has low oxygen diffusion properties and an excellent adhesion to the refractory metal.

7. The cermet material of claim 6 that is deposited at between 0.2 to 0.8 Pascal, and where the power density for the high metal volume fraction is between 1.5-3.5 W/cm² for both the aluminum and metallic particle providing cathode; the power density for the low metal volume fraction is between 1.5-3.5 W/cm\hat{ }2 W/cm² for the aluminum providing cathode, and 0.5-1.5 W/cm² for metallic alloy particle providing cathode.

8. The cermet material of claim 1 containing metal particles that comprise a refractory metal or element selected from the grout consisting of Nb, Ta, Ni, Mo, Tungsten Cr, Al, Ti, and Si deposited from the same cathode that will passivate the metal particle during an oxidizing process and form on top of these metal particles an oxygen diffusion barrier.

9. The cermet material of claim 1, wherein the alloys that form high temperature passivating layers are NiCr alloys, NiCrAlY, metal silicides, metal titanium alloys, and mixtures of the foregoing.

10. The cermet material of claim 7, wherein the cathode providing the metallic particles are NiCr or NiCrAlY.

11. The cermet material of claim 1, wherein the dielectric is formed by adding oxygen as a reactive gas into a deposition chamber and using a pulsed DC power supply.

12. The cermet material of claim 1, wherein the dielectric is formed by depositing an alumina or alumina alloy directly from an alumina or alumina alloy target by radio frequency deposition.

13. The cermet material of claim 1, that requires a heat treatment above 350° C. in an oxidizing atmosphere to passivate.

14. The cermet material of claim 2, deposited on an infrared reflector.

15. The cermet material of claim 5, wherein the anti reflective coating is a layer containing SiO2.

16. The cermet material of claim 4, where on top of the cermet an anti reflective coating is posited.

17. The cermet material of claim 4 containing metal particles that comprise a refractory metal or element selected from the group consisting of Nb, Ta, Ni, Mo, Tungsten Cr, Al, Ti, and Si deposited from the same cathode that will passivate the metal particle during an oxidizing process and form on top of these metal particles an oxygen diffusion barrier.

18. The cermet material of claim 5 containing metal particles that comprise a refractory metal or element selected from the group consisting of Nb, Ta, Ni, Mo, Tungsten Cr, Al, Ti, and Si deposited from the same cathode that will passivate the metal particle during an oxidizing process and form on top of these metal particles an oxygen diffusion barrier.

19. The cermet material of claim 6 containing metal particles that comprise a refractory metal or element selected from the group consisting of Nb, Ta, Ni, Mo, Tungsten Cr, Al, Ti, and Si deposited from the same cathode that will passivate the metal particle during an oxidizing process and form on top of these metal particles an oxygen diffusion barrier.

20. The cermet material of claim 7 containing metal particles that comprise a refractory metal or element selected from the group consisting of Nb, Ta, Ni, Mo, Tungsten Cr, Al, Ti, and Si deposited from the same cathode that will passivate the metal particle during an oxidizing process and form on top of these metal particles an oxygen diffusion barrier.
